(19) United States
(12) Patent Application Publication
(10) Pub. No.: US 2023/0335551 A1
(43) Pub. Date: Oct. 19, 2023

(54) SEMICONDUCTOR DEVICE AND METHOD OF MANUFACTURE

(71) Applicant: Taiwan Semiconductor Manufacturing Co., Ltd., Hsinchu (TW)

(72) Inventors: Yao-Teng Chuang, Hsinchu (TW); Kuei-Lun Lin, Keelung City (TW); Te-Yang Lai, Hsinchu (TW); Da-Yuan Lee, Jhubei City (TW); Weng Chang, Hsinchu (TW); Chi On Chui, Hsinchu (TW)

(21) Appl. No.: 17/896,970

(22) Filed: Aug. 26, 2022

Related U.S. Application Data
(60) Provisional application No. 63/362,925, filed on Apr. 13, 2022.

(51) Int. Cl. H01L 27/088; H01L 21/8234

(52) U.S. Cl. CPC H01L 27/0886; H01L 21/823431

(57) ABSTRACT

Semiconductor devices and methods of manufacturing semiconductor devices with differing threshold voltages are provided. In embodiments the threshold voltages of individual semiconductor devices are tuned through the deposition, diffusion, and removal of dipole materials in order to provide different dipole regions within different transistors. These different dipole regions cause the different transistors to have different threshold voltages.

### PRIORITY CLAIM AND CROSS-REFERENCE

This application claims the benefit of U.S. Provisional Application No. 63/362,925, filed on Apr. 13, 2022, which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of a formation of semiconductor fins, in accordance with some embodiments.

FIG. 2 illustrates formation of source/drain regions, in accordance with some embodiments.

FIG. 3 illustrates deposition of a first dopant layer, in accordance with some embodiments.

FIG. 4 illustrates a patterning of the first dopant layer, in accordance with some embodiments.

FIGS. 5A-5B illustrate a first annealing process, in accordance with some embodiments.

FIGS. 6A-6B illustrate a removal of the first dopant layer, in accordance with some embodiments.

FIGS. 7A-7B illustrate deposition of a second dopant layer, in accordance with some embodiments.

FIGS. 8A-8B illustrate a second annealing process, in accordance with some embodiments.

FIGS. 9A-9B illustrate deposition of a third dopant layer, in accordance with some embodiments.

FIGS. 10A-10B illustrate a patterning of the third dopant layer, in accordance with some embodiments.

FIGS. 11A-11B illustrate a third annealing process, in accordance with some embodiments.

FIGS. 12A-12B illustrate a removal of the third dopant layer, in accordance with some embodiments.

FIG. 13 illustrates deposition of a fill material, in accordance with some embodiments.

FIGS. 14A-14B illustrate formation of transistors, in accordance with some embodiments.

FIG. 15 illustrates deposition of an interfacial layer, in accordance with some embodiments.

FIG. 16 illustrates formation of dipole regions within the interfacial layer, in accordance with some embodiments.

FIG. 17 illustrates formation of transistors with the dipole regions within the interfacial layer, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will now be described with respect to particular examples including finFET devices that utilize volume free dipole layers in order to form multiple transistors, wherein each of the multiple transistors is formed with a different threshold voltage. In some embodiments the transistors can be implemented in 5 nm or 3 nm technology nodes with voltages of about 290 mV. Using the embodiments such as those described herein may provide at least eight different threshold voltages with only three separate patterning processes. However, embodiments are not limited to the examples provided herein, and the ideas may be implemented in a wide array of embodiments, such as embodiments implemented within gate all around structures.

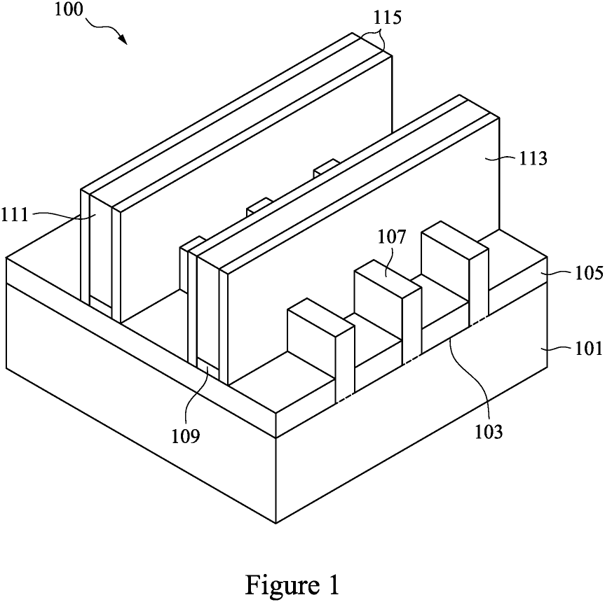

With reference now to FIG. 1, there is illustrated a perspective view of a semiconductor device 100 such as a finFET device. In an embodiment the semiconductor device 100 comprises a substrate 101 and first trenches 103. The substrate 101 may be a silicon substrate, although other substrates, such as semiconductor-on-insulator (SOI), strained SOI, and silicon germanium on insulator, could be used. The substrate 101 may be a p-type semiconductor, although in other embodiments, it could be an n-type semiconductor.

The first trenches 103 may be formed as an initial step in the eventual formation of first isolation regions 105. The first trenches 103 may be formed using a masking layer (not separately illustrated in FIG. 1) along with a suitable etching process. For example, the masking layer may be a hardmask comprising silicon nitride formed through a process such as chemical vapor deposition (CVD), although other materials, such as oxides, oxynitrides, silicon carbide, combinations of these, or the like, and other processes, such as plasma enhanced chemical vapor deposition (PECVD), low pressure chemical vapor deposition (LPCVD), or even silicon oxide formation followed by nitridation, may be utilized. Once formed, the masking layer may be patterned through a suitable photolithographic process to expose those portions of the substrate 101 that will be removed to form the first trenches 103.

As one of skill in the art will recognize, however, the processes and materials described above to form the masking layer are not the only method that may be used to protect portions of the substrate 101 while exposing other portions of the substrate 101 for the formation of the first trenches 103. Any suitable process, such as a patterned and developed photoresist, may be utilized to expose portions of the substrate 101 to be removed to form the first trenches 103. All such methods are fully intended to be included in the scope of the present embodiments.

Once a masking layer has been formed and patterned, the first trenches 103 are formed in the substrate 101. The exposed substrate 101 may be removed through a suitable process such as reactive ion etching (RIE) in order to form the first trenches 103 in the substrate 101, although any suitable process may be used. In an embodiment, the first trenches 103 may be formed to have a first depth of less than about 5,000 Å from the surface of the substrate 101, such as about 2,500 Å.

However, as one of ordinary skill in the art will recognize, the process described above to form the first trenches 103 is merely one potential process, and is not meant to be the only embodiment. Rather, any suitable process through which the first trenches 103 may be formed may be utilized and any suitable process, including any number of masking and removal steps may be used.

In addition to forming the first trenches 103, the masking and etching process additionally forms fins 107 from those portions of the substrate 101 that remain unremoved. For convenience the fins 107 have been illustrated in the figures as being separated from the substrate 101 by a dashed line, although a physical indication of the separation may or may not be present. These fins 107 may be used, as discussed below, to form the channel region of multiple-gate FinFET transistors. While FIG. 1 only illustrates three fins 107 formed from the substrate 101, any number of fins 107 may be utilized.

The fins 107 may be formed such that they have a width at the surface of the substrate 101 of between about 5 nm and about 80 nm, such as about 30 nm. Additionally, the fins 107 may be spaced apart from each other by a distance of between about 10 nm and about 100 nm, such as about 50 nm. By spacing the fins 107 in such a fashion, the fins 107 may each form a separate channel region while still being close enough to share a common gate (discussed further below).

Once the first trenches 103 and the fins 107 have been formed, the first trenches 103 may be filled with a dielectric material and the dielectric material may be recessed within the first trenches 103 to form the first isolation regions 105. The dielectric material may be an oxide material, a high-density plasma (HDP) oxide, or the like. The dielectric material may be formed, after an optional cleaning and lining of the first trenches 103, using either a chemical vapor deposition (CVD) method (e.g., the HARP process), a high density plasma CVD method, or other suitable method of formation as is known in the art.

The first trenches 103 may be filled by overfilling the first trenches 103 and the substrate 101 with the dielectric material and then removing the excess material outside of the first trenches 103 and the fins 107 through a suitable process such as chemical mechanical polishing (CMP), an etch, a combination of these, or the like. In an embodiment, the removal process removes any dielectric material that is located over the fins 107 as well, so that the removal of the dielectric material will expose the surface of the fins 107 to further processing steps.

Once the first trenches 103 have been filled with the dielectric material, the dielectric material may then be recessed away from the surface of the fins 107. The recessing may be performed to expose at least a portion of the sidewalls of the fins 107 adjacent to the top surface of the fins 107. The dielectric material may be recessed using a wet etch by dipping the top surface of the fins 107 into an etchant such as HF, although other etchants, such as H₂, and other methods, such as a reactive ion etch, a dry etch with etchants such as NH₃/NF₃, chemical oxide removal, or dry chemical clean may be used. The dielectric material may be recessed to a distance from the surface of the fins 107 of between about 50 Å and about 500 Å, such as about 400 Å. Additionally, the recessing may also remove any leftover dielectric material located over the fins 107 to ensure that the fins 107 are exposed for further processing.

As one of ordinary skill in the art will recognize, however, the steps described above may be only part of the overall process flow used to fill and recess the dielectric material. For example, lining steps, cleaning steps, annealing steps, gap filling steps, combinations of these, and the like may also be utilized to form and fill the first trenches 103 with the dielectric material. All of the potential process steps are fully intended to be included within the scope of the present embodiment.

After the first isolation regions 105 have been formed, a dummy gate dielectric 109, a dummy gate electrode 111 over the dummy gate dielectric 109, and first spacers 113 may be formed over each of the fins 107. In an embodiment the dummy gate dielectric 109 may be formed by thermal oxidation, chemical vapor deposition, sputtering, or any other methods known and used in the art for forming a gate dielectric. Depending on the technique of gate dielectric formation, the dummy gate dielectric 109 thickness on the top of the fins 107 may be different from the gate dielectric thickness on the sidewall of the fins 107.

The dummy gate dielectric 109 may comprise a material such as silicon dioxide or silicon oxynitride with a thickness ranging from about 3 angstroms to about 100 angstroms, such as about 10 angstroms. The dummy gate dielectric 109 may be formed from a high permittivity (high-k) material (e.g., with a relative permittivity greater than about 5) such as lanthanum oxide (La₂O₃), aluminum oxide (Al₂O₃), hafnium oxide (HfO₂), hafnium oxynitride (HfON), or zirconium oxide (ZrO₂), or combinations thereof, with an equivalent oxide thickness of about 0.5 angstroms to about 100 angstroms, such as about 10 angstroms or less. Additionally, any combination of silicon dioxide, silicon oxynitride, and/or high-k materials may also be used for the dummy gate dielectric 109.

The dummy gate electrode 111 may comprise a conductive or non-conductive material and may be selected from a group comprising polysilicon, W, Al, Cu, AlCu, W, Ti, TiAlN, TaC, TaCN, TaSiN, Mn, Zr, TiN, Ta, TaN, Co, Ni, combinations of these, or the like. The dummy gate electrode 111 may be deposited by chemical vapor deposition (CVD), sputter deposition, or other techniques known and used in the art for depositing conductive materials. The thickness of the dummy gate electrode 111 may be in the range of about 5 Ǻ to about 200 Ǻ. The top surface of the dummy gate electrode 111 may have a non-planar top surface, and may be planarized prior to patterning of the dummy gate electrode 111 or gate etch. Ions may or may not be introduced into the dummy gate electrode 111 at this point. Ions may be introduced, for example, by ion implantation techniques.

Once formed, the dummy gate dielectric 109 and the dummy gate electrode 111 may be patterned to form a series of stacks 115 over the fins 107. The stacks 115 define multiple channel regions located on each side of the fins 107 beneath the dummy gate dielectric 109. The stacks 115 may be formed by depositing and patterning a gate mask (not separately illustrated in FIG. 1) on the dummy gate electrode 111 using, for example, deposition and photolithography techniques known in the art. The gate mask may incorporate commonly used masking and sacrificial materials, such as (but not limited to) silicon oxide, silicon oxynitride, SiCON, SiC, SiOC, and/or silicon nitride and may be deposited to a thickness of between about 5 Ǻ and about 200 Ǻ. The dummy gate electrode 111 and the dummy gate dielectric 109 may be etched using a dry etching process to form the patterned stacks 115.

Once the stacks 115 have been patterned, the first spacers 113 may be formed. The first spacers 113 may be formed on opposing sides of the stacks 115. The first spacers 113 are typically formed by blanket depositing a spacer layer (not separately illustrated in FIG. 1) on the previously formed structure. The spacer layer may comprise SiN, oxynitride, SiC, SiON, SiOCN, SiOC, oxide, and the like and may be formed by methods utilized to form such a layer, such as chemical vapor deposition (CVD), plasma enhanced CVD, sputter, and other methods known in the art. The spacer layer may comprise a different material with different etch characteristics or the same material as the dielectric material within the first isolation regions 105. The first spacers 113 may then be patterned, such as by one or more etches to remove the spacer layer from the horizontal surfaces of the structure, to form the first spacers 113.

In an embodiment the first spacers 113 may be formed to have a thickness of between about 5 Ǻ and about 500 Ǻ. Additionally, once the first spacers 113 have been formed, a first spacer 113 adjacent to one stack 115 may be separated from a first spacer 113 adjacent to another stack 115 by a distance of between about 5 nm and about 200 nm, such as about 20 nm. However, any suitable thicknesses and distances may be utilized.

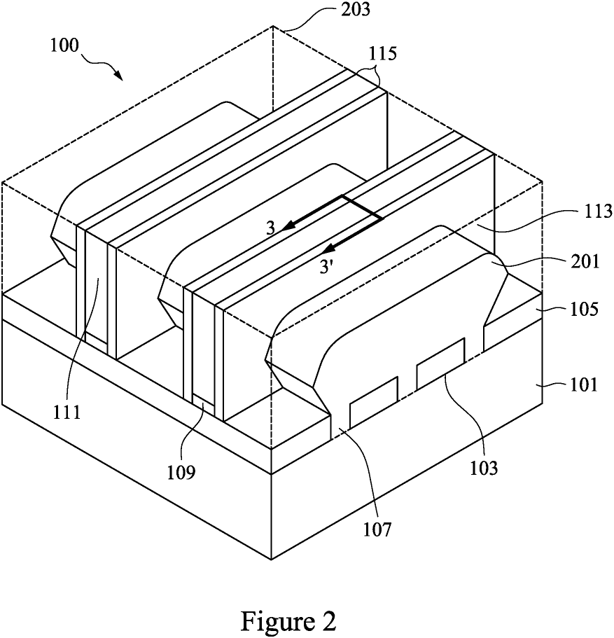

FIG. 2 illustrates a removal of the fins 107 from those areas not protected by the stacks 115 and the first spacers 113 and a regrowth of source/drain regions 201. The removal of the fins 107 from those areas not protected by the stacks 115 and the first spacers 113 may be performed by a reactive ion etch (RIE) using the stacks 115 and the first spacers 113 as hardmasks, or by any other suitable removal process. The removal may be continued until the fins 107 are either planar with (as illustrated) or below the surface of the first isolation regions 105.

Once these portions of the fins 107 have been removed, a hard mask (not separately illustrated), is placed and patterned to cover the dummy gate electrode 111 to prevent growth and the source/drain regions 201 may be regrown in contact with each of the fins 107. In an embodiment the source/drain regions 201 may be regrown and, in some embodiments the source/drain regions 201 may be regrown to form a stressor that will impart a stress to the channel regions of the fins 107 located underneath the stacks 115. In an embodiment wherein the fins 107 comprise silicon and the FinFET is a p-type device, the source/drain regions 201 may be regrown through a selective epitaxial process with a material, such as silicon or else a material such as silicon germanium that has a different lattice constant than the channel regions. The epitaxial growth process may use precursors such as silane, dichlorosilane, germane, and the like, and may continue for between about 5 minutes and about 120 minutes, such as about 30 minutes.

In some embodiments the source/drain regions 201 may be formed to have a thickness of between about 5 Ǻ and about 1000 Ǻ and a height over the first isolation regions 105 of between about 10 Ǻ and about 500 Ǻ, such as about 200 Ǻ. In this embodiment, the source/drain regions 201 may be formed to have a height above the upper surface of the first isolation regions 105 of between about 5 nm and about 250 nm, such as about 100 nm. However, any suitable height may be utilized.

Once the source/drain regions 201 are formed, dopants may be implanted into the source/drain regions 201 by implanting appropriate dopants to complement the dopants in the fins 107. For example, p-type dopants such as boron, gallium, indium, or the like may be implanted to form a PMOS device. Alternatively, n-type dopants such as phosphorous, arsenic, antimony, or the like may be implanted to form an NMOS device. These dopants may be implanted using the stacks 115 and the first spacers 113 as masks. It should be noted that one of ordinary skill in the art will realize that many other processes, steps, or the like may be used to implant the dopants. For example, one of ordinary skill in the art will realize that a plurality of implants may be performed using various combinations of spacers and liners to form source/drain regions having a specific shape or characteristic suitable for a particular purpose. Any of these processes may be used to implant the dopants, and the above description is not meant to limit the present embodiments to the steps presented above.

Additionally at this point the hard mask that covered the dummy gate electrode 111 during the formation of the source/drain regions 201 may be removed. In an embodiment the hard mask may be removed using, e.g., a wet or dry etching process that is selective to the material of the hard mask. However, any suitable removal process may be utilized. In some embodiments, the hard mask may remain and be removed later during replacement gate processing.

FIG. 2 also illustrates a formation of an inter-layer dielectric (ILD) layer 203 (illustrated in dashed lines in FIG. 2 in order to more clearly illustrate the underlying structures) over the stacks 115 and the source/drain regions 201. The ILD layer 203 may comprise a material such as boron phosphorous silicate glass (BPSG), although any suitable dielectrics may be used. The ILD layer 203 may be formed using a process such as PECVD, although other processes, such as LPCVD, may alternatively be used. The ILD layer 203 may be formed to a thickness of between about 100 Å and about 3,000 Å. Once formed, the ILD layer 203 may be planarized with the first spacers 113 using, e.g., a planarization process such as chemical mechanical polishing process, although any suitable process may be utilized.

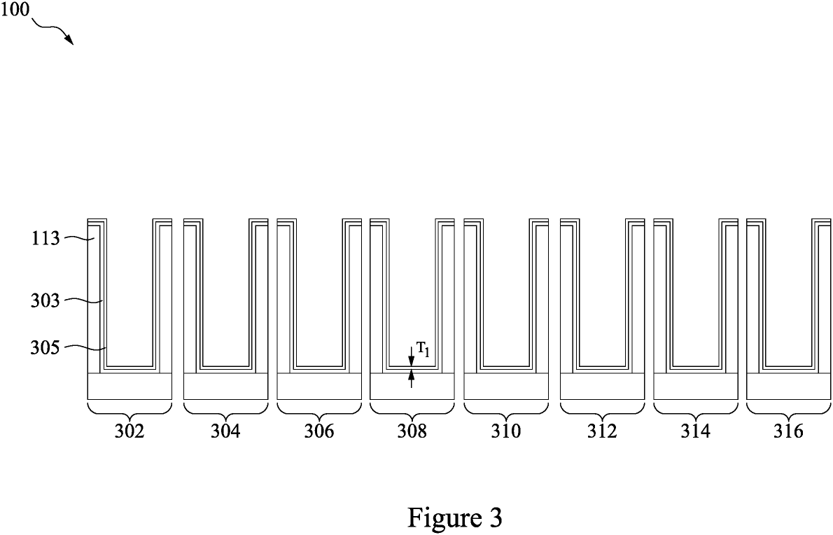

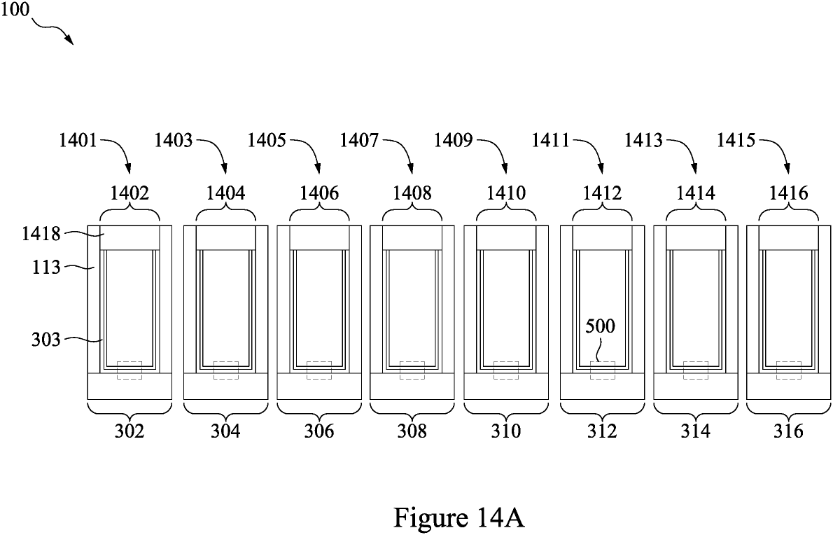

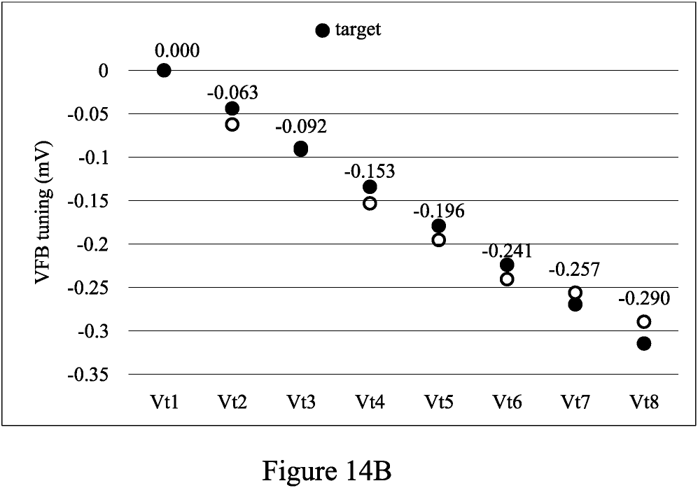

FIG. 3 illustrates a cross-sectional view of FIG. 2 along line 3-3′ in order to better illustrate a removal and replacement of the material of the dummy gate electrode 111 and the dummy gate dielectric 109 with a plurality of layers for a first gate stack 1402 (not illustrated in FIG. 3 but illustrated and described below with respect to FIG. 14A). Additionally in FIG. 3, while the first gate stack 1402 is illustrated as being within a first region 302 of the substrate 101, there is also illustrated a second region 304 (for a second gate stack 1404) of the substrate 101, a third region 306 (for a third gate stack 1406) of the substrate 101, a fourth region 308 (for a fourth gate stack 1408), a fifth region 310 (for a fifth gate stack 1410), a sixth region 312 (for a sixth gate stack 1412), a seventh region 314 (for a seventh gate stack 1414), and an eighth region 316 (for an eighth gate stack 1416) of the substrate 101. In an embodiment the first gate stack 1402 may be a gate stack for a first transistor 1401 (e.g., a first NMOS finFET transistor) with a first voltage threshold Vtl, the second gate stack 1404 may be for a second transistor 1403 (e.g., a second NMOS finFET transistor) with a second voltage threshold Vt2 different from the first voltage threshold Vtl, the third gate stack 1406 may be for a third transistor 1405 (e.g., a second NMOS finFET transistor) with a third voltage threshold Vt3 different from the first voltage threshold Vt1 and the second voltage threshold Vt2), the fourth gate stack 1408 may be for a fourth transistor 1407 with a fourth voltage threshold Vt4, the fifth gate stack 1410 may be for a fifth transistor 1409 with a fifth voltage threshold Vt5, the sixth gate stack 1412 may be for a sixth transistor 1411 with a sixth voltage threshold Vt6, the seventh gate stack 1414 may be for a seventh transistor 1413 with a seventh voltage threshold Vt7, and the eighth gate stack 1416 may be for an eighth transistor 1415 with an eighth voltage threshold Vt8. However, any suitable devices may be utilized.

In an embodiment the dummy gate electrode 111 and the dummy gate dielectric 109 may be removed using, e.g., one or more wet or dry etching processes that utilize etchants that are selective to the material of the dummy gate electrode 111 and the dummy gate dielectric 109. However, any suitable removal process or processes may be utilized.

Once the dummy gate electrode 111 and the dummy gate dielectric 109 have been removed, a process to form the first gate stack 1402, the second gate stack 1404, the third gate stack 1406, the fourth gate stack 1408, the fifth gate stack 1410, the sixth gate stack 1412, the seventh gate stack 1414, and the eighth gate stack 1416 may be begun by depositing a series of layers. In an embodiment the series of layers may include an optional interfacial layer (not separately illustrated in FIG. 3), a first dielectric layer 303, and a first dopant layer 305.

The optional interfacial layer may be formed prior to the formation of the first dielectric layer 303. In an embodiment the interfacial layer may be a material such as silicon dioxide formed through a process such as in situ steam generation (ISSG). In another embodiment the interfacial layer may be a high-k material such as HfO₂, HfSiO, HfSiON, HfTaO, HfTiO, HfZrO, LaO, ZrO, Ta₂O₅, combinations of these, or the like, to a thickness of between about 5 Ǻ and about 20 Ǻ, such as about 10 Ǻ. However, any suitable material or process of formation may be utilized.

Once the interfacial layer is formed, the first dielectric layer 303 may be formed over the interfacial layer. In an embodiment the first dielectric layer 303 is a high-k material such as HfO₂, HfSiO, HfSiON, HfTaO, HfTiO, HfZrO, LaO, ZrO, Ta₂O₅, combinations of these, or the like, deposited through a process such as atomic layer deposition, chemical vapor deposition, or the like. The first dielectric layer 303 may be deposited to a thickness of between about 5 Ǻ and about 20 Ǻ, although any suitable material and thickness may be utilized. If the thickness of the first dielectric layer 303 is too small, the device will suffer from gate leakage issues, while if the thickness is too large, the first dielectric layer 303 will undesirably interfere with the deposition of subsequent materials.

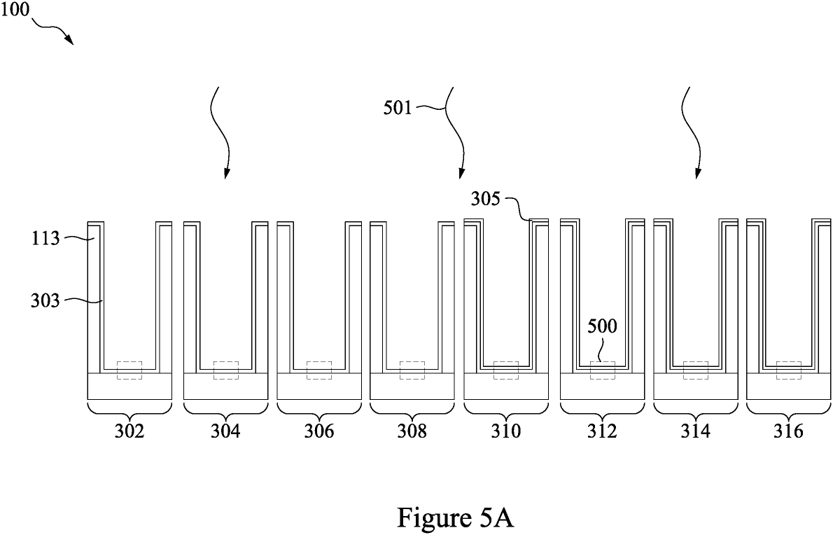

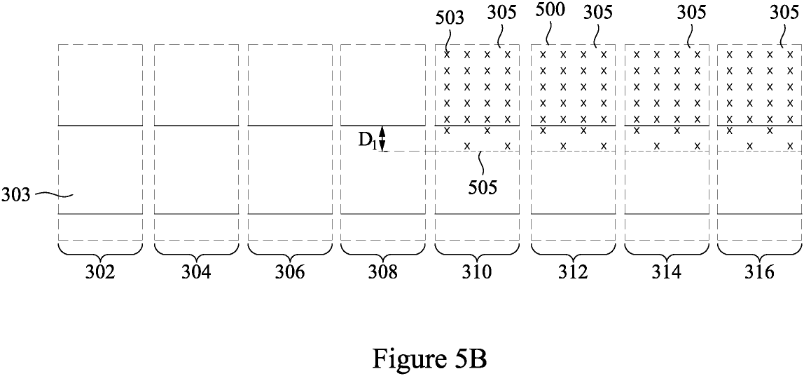

The first dopant layer 305 is formed over the first dielectric layer 303 and will be used as a source to introduce first dipole dopants 503 (not individually illustrated in FIG. 3 but illustrated and discussed further in FIGS. 5 below) into the first dielectric layer 303. In an embodiment the first dipole dopants 503 are utilized within the first dielectric layer 303 of the transistors to create a dipole field within the first dielectric layer 303, thereby modifying the voltage threshold without the need for work function tuning layers. As such, in some embodiments the first dipole dopants 503 may be a metal such as lanthanum, aluminum, magnesium, strontium, yttrium, an element having an electronegativity smaller than Hf, combinations of these, or the like. In other embodiments, the first dipole dopants 503 may include p-type dopant materials, such as titanium, aluminum, gallium, indium, niobium, zinc, an element having an electronegativity greater than Hf, combinations of these, or the like.

In embodiments in which the first dipole dopants 503 are metals, the first dopant layer 305 may be an oxide of the desired dipole dopant. For example, in an embodiment in which the first dipole dopants 503 are lanthanum, the first dopant layer 305 may be an oxide such as lanthanum oxide. Similarly, in an embodiment in which the first dipole dopants 503 are aluminum, the first dopant layer 305 may be an oxide such as aluminum oxide. However, any suitable material may be utilized.

The first dopant layer 305 may be deposited using a deposition process such as atomic layer deposition, chemical vapor deposition, physical vapor deposition, combinations of these, or the like. Additionally, the first dopant layer 305 may be deposited to any suitable thickness, and different thicknesses (achieved by using a different number of ALD cycles) may be used to achieve different threshold voltages.

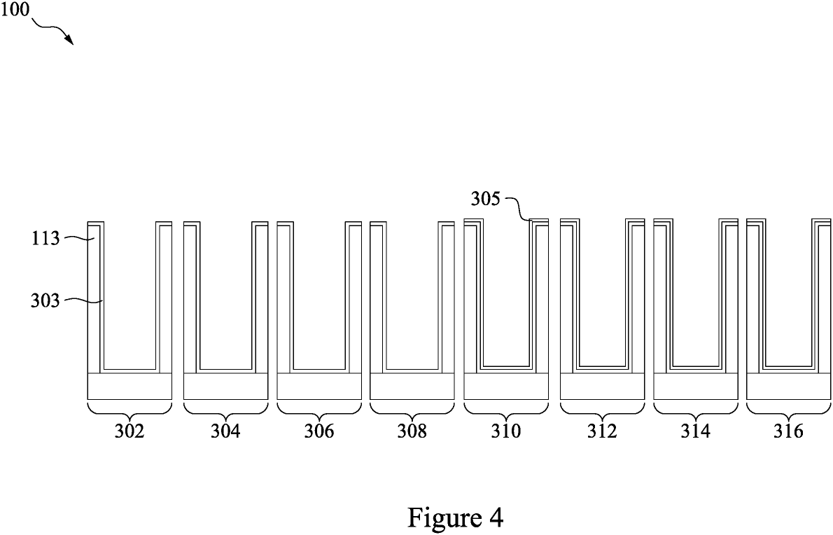

FIG. 4 illustrates a patterning of the first dopant layer 305 to remove the first dopant layer 305 from the first region 302, the second region 304, the third region 306, and the fourth region 308. In an embodiment the patterning of the first dopant layer 305 may be performed using, e.g., a photolithographic masking and etching process, whereby a photoresist may be deposited, imaged, and developed to create a mask covering the fifth region 310, the sixth region 312, the seventh region 314, and the eighth region 316. Once the mask is in place, one or more etching processes, such as one or more wet or dry etches, may be performed to remove the first dopant layer 305 from the first region 302, the second region 304, the third region 306, and the fourth region 308. However, any suitable process may be utilized.

FIG. 5A illustrates a first annealing process (represented by the curved arrows labeled 501) that is utilized to drive the first dipole dopants 503 from the first dopant layer 305 into the first dielectric layer 303 over the fifth region 310, the sixth region 312, the seventh region 314, and the eighth region 316 (but not into the first region 302, the second region 304, the third region 306, or the fourth region 308 because the first dopant layer 305 has been removed from these regions). In an embodiment the first annealing process 501 may be a thermal anneal wherein the substrate 101 and overlying structures are heated within, e.g., in a furnace, within an inert atmosphere. The first anneal process may be performed at a temperature sufficient to achieve the desired threshold voltages, with different temperatures being used to achieve different threshold voltages. In particular embodiments, the temperature may be between about 500° C. and about 950° C. If the temperature of the first annealing process 501 is over 950° C., the overall thermal budget might impact junction and cause other issues with process integration. Further, if the temperature if below about 500° C., the dipole cannot form and won’t achieve the desired multiple voltage thresholds.

FIG. 5B illustrates a close up view of the dashed boxes 500 in FIG. 5A, and illustrates the diffusion of the first dipole dopants 503 (represented in FIG. 5B by the Xs labeled 503) from the first dopant layer 305 into the first dielectric layer 303 to form first dipole regions 505. As the first dipole dopants 503 diffuse into the first dielectric layer 303, the first dipole dopants 503 form the first dipole regions 505 with a concentration gradient of the first dipole dopants 503 reaching into the first dielectric layer 303 to a first distance D₁. However, any suitable distances may be utilized.

However, while the first dipole regions 505 are formed within the fifth region 310, the sixth region 312, the seventh region 314, and the eighth region 316, the first dipole regions 505 are not formed over all of the regions. In particular, because the first dopant layer 305 has been removed from the first region 302, the second region 304, the third region 306, and the fourth region 308, there are no first dopant layer 305 present over these regions, and the first dipole regions 505 are not formed.

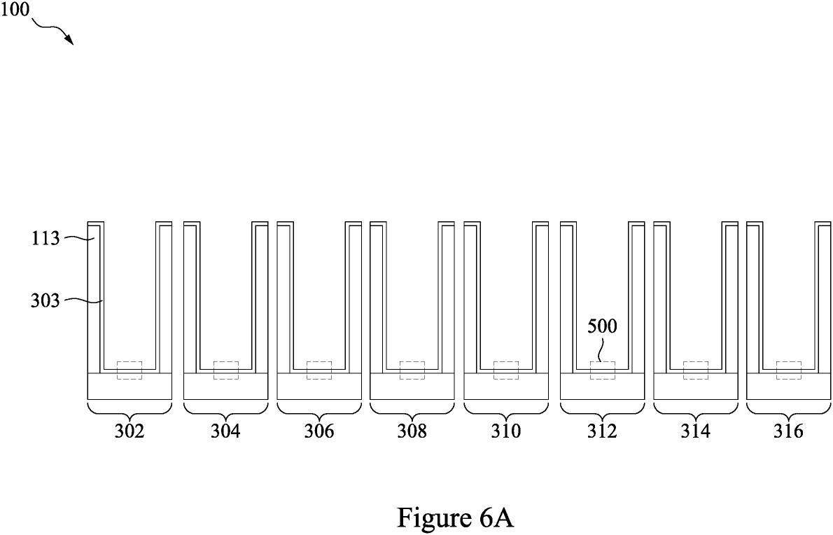

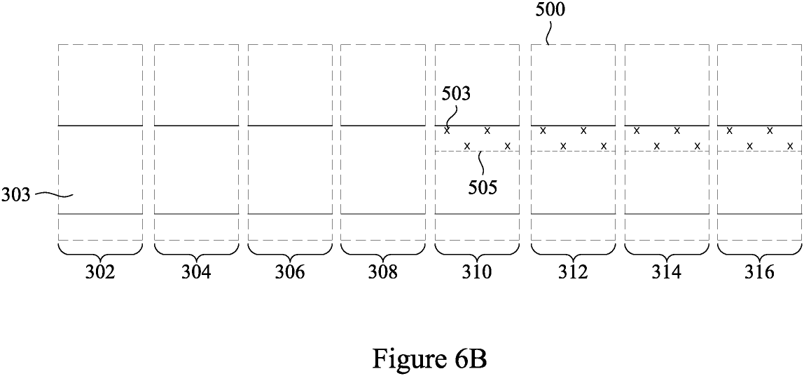

FIGS. 6A-6B illustrate a removal of the first dopant layer 305 after formation of the first dipole regions 505, with FIG. 6B illustrating a similar view of the dashed boxes 500 as FIG. 5B). In an embodiment the first dopant layer 305 may be removed using one or more etching processes, such as one or more wet or dry etches. However, any suitable methods of removal may be utilized.

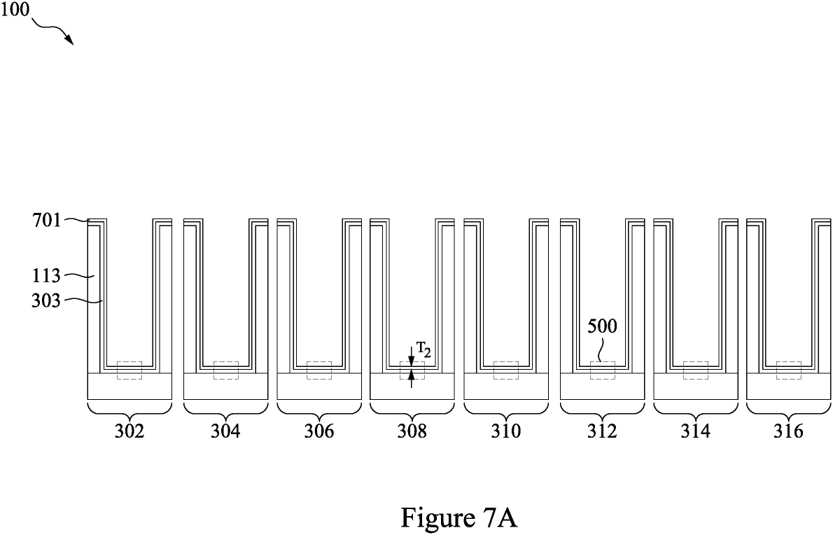

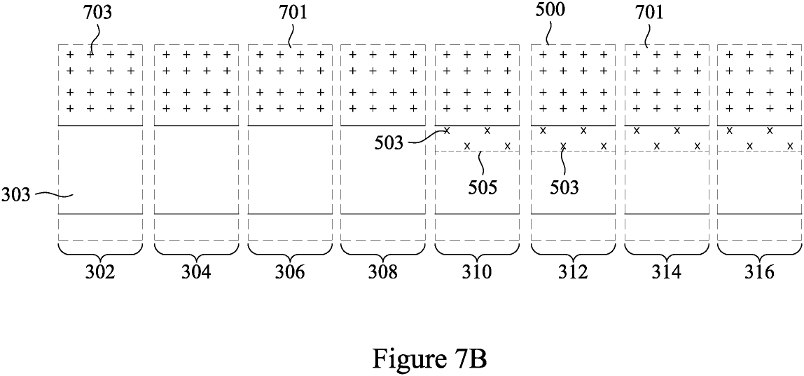

FIGS. 7A-7B illustrate a deposition of a second dopant layer 701 with second dipole dopants (represented in FIG. 7B by the “+”s labeled 703) over each of the first region 302, the second region 304, the third region 306, the fourth region 308, the fifth region 310, the sixth region 312, the seventh region 314, and the eighth region 316, with FIG. 7B illustrating a similar view of the dashed boxes 500 as FIG. 5B. In an embodiment the second dipole dopants 703 may be the same as, similar to, or different from the first dipole dopants 503 and, if similar to or different from, may be chosen to work either independently from or else with the first dipole dopants 503 to tune the desired voltage threshold.

In an embodiment the second dopant layer 701 may be a similar material as the first dopant layer 305 (described above with respect to FIG. 3), such as by being an oxide of the desired dipole dopant such as lanthanum oxide or aluminum oxide. In particular embodiments the second dopant layer 701 may be the same or a different material from the first dopant layer 305. For example, in an embodiment in which the first dopant layer 305 is lanthanum oxide, the second dopant layer 701 may be lanthanum oxide as well, or else may be a different material such as aluminum oxide. However, any suitable material may be utilized.

Additionally, the second dopant layer 701 may be deposited to a second thickness that is the same as or different from the first dopant layer 305. As additional examples, the first thickness may be less than the second thickness, or the first thickness may be greater than the second thickness. However, any suitable thickness may be utilized.

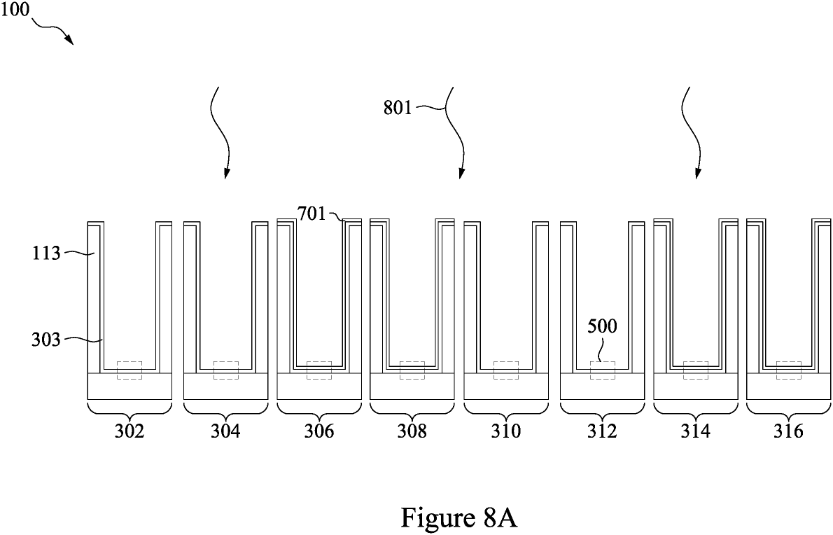

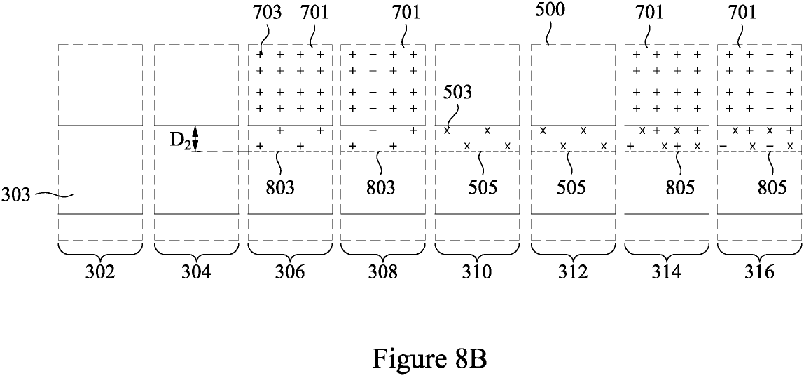

FIGS. 8A-8B illustrate a patterning of the second dopant layer 701 and a second annealing process (represented by the curved arrows labeled 801). In an embodiment the second dopant layer 701 is patterned using, e.g., a masking and etching process, in order to remove the second dopant layer 701 from the first region 302, the second region 304, the fifth region 310, or the sixth region 312 and to leave the second dopant layer 701 over the third region 306, the fourth region 308, the seventh region 314, and the eighth region 316.

Once the second dopant layer 701 has been deposited and patterned (and any masks have been removed), the second annealing process 801 is utilized in order to drive the second dipole dopants 703 from the second dopant layer 701 into the first dielectric layer 303 over the third region 306, the fourth region 308, the seventh region 314, and the eighth region 316 (but not into the first region 302, the second region 304, the fifth region 310, or the sixth region 312 because the second dopant layer 701 has been removed from these regions).

In an embodiment the second annealing process 801 may be similar to the first annealing process 501, and may be a thermal anneal wherein the substrate 101 and overlying structures are heated within, e.g., in a furnace, within an inert atmosphere. The second annealing process 801 may be performed at a temperature of between about 500° C. and about 950° C. If the temperature of the second anneal process 801 is over 950° C., the overall thermal budget might impact junction and cause issue with process integration. Further, if the temperature if below about 500° C., the dipole cannot form and won’t achieve the desired multiple voltage thresholds.

FIG. 8B illustrates a close up view of the dashed boxes 500 in FIG. 8A, and illustrates the diffusion of the second dipole dopants 703 from the second dopant layer 701 into the first dielectric layer 303 to form a second dipole region 803 (in the third region 306 and the fourth region 308) and a third dipole region 805 (in the seventh region 314 and the eighth region 316). In this embodiment the second dipole region 803 comprises dipole dopants of only the second dipole dopants 703 while the third dipole region 805 comprises dipole dopants of both the first dipole dopants 503 and the second dipole dopants 703.

As the second dipole dopants 703 diffuse into the first dielectric layer 303 and form the second dipole region 803, the third dipole region 805 is formed with a concentration gradient of the second dipole dopants 703 reaching into the first dielectric layer 303 to a second distance D₂. However, any suitable distances may be utilized.

Additionally, while the second dipole region 803 has been formed within the third region 306 and the fourth region 308, and while the third dipole region 805 has been formed within the seventh region 314 and the eighth region 316, the second dipole region 803 and the third dipole region 805 are not formed over all of the regions. In particular, because the second dopant layer 701 has been removed from the first region 302, the second region 304, the fifth region 310, and the sixth region 312, these regions are not affected. As such, at this point in the process, the first dielectric layer 303 within the first region 302 and the second region 304 remain free of dipole dopants, and the first dipole regions 505 within the fifth region 310 and the sixth region remain unchanged with only the first dipole dopants 503 being present.

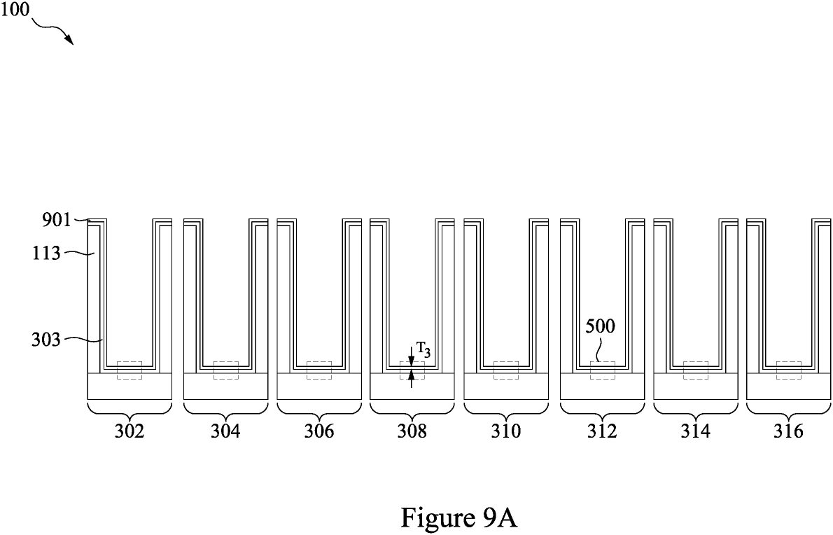

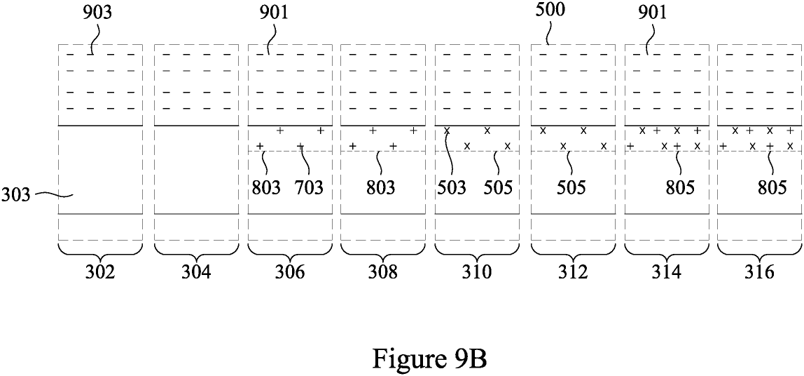

FIGS. 9A-9B illustrate a deposition of a third dopant layer 901 with third dipole dopants 903 in each of the first region 302, the second region 304, the third region 306, the fourth region 308, the fifth region 310, the sixth region 312, the seventh region 314, and the eighth region 316, with FIG. 9B illustrating a similar view of the dashed boxes 500 as FIG. 5B). In an embodiment the third dipole dopants 903 may be similar to, the same as, or different from the first dipole dopants 503 and/or the second dipole dopants 703 and may be chosen to work either independently from or with the first dipole dopants 503 and the second dipole dopants 703 to tune the desired voltage threshold.

In an embodiment the third dopant layer 901 may be a similar material as the first dopant layer 305 (described above with respect to FIG. 3), such as by being a dipole dopant containing material such as lanthanum oxide or aluminum oxide. In particular embodiments the third dopant layer 901 may be the same or a different material from the first dopant layer 305 and/or the second dopant layer 701. For example, in an embodiment in which the first dopant layer 305 and/or the second dopant layer 701 is lanthanum oxide, the third dopant layer 901 may be lanthanum oxide as well, or else may be a different material such as aluminum oxide. However, any suitable material may be utilized.

Additionally, the third dopant layer 901 may be deposited to a third thickness that is the same as or different from the first dopant layer 305. For example, the third thickness may be less than the first thickness and/or the second thickness, or the third thickness may be greater than the first thickness and/or the second thickness. However, any suitable thickness may be utilized.

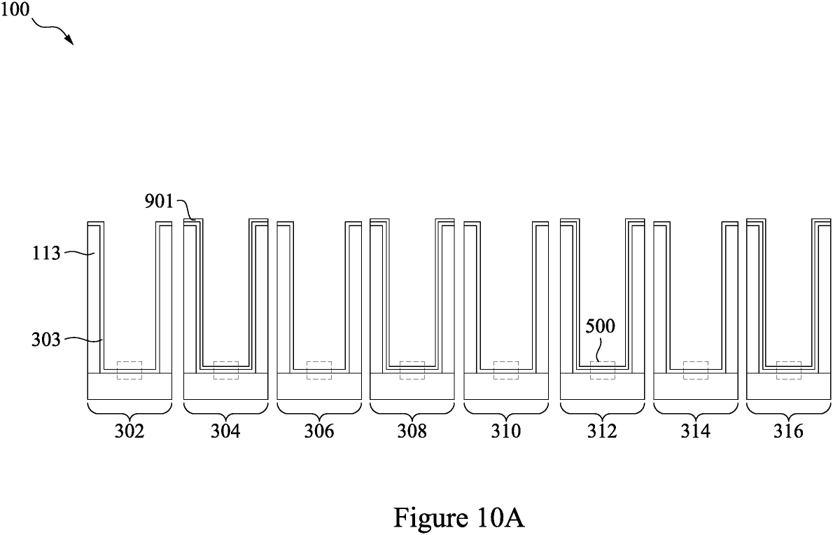

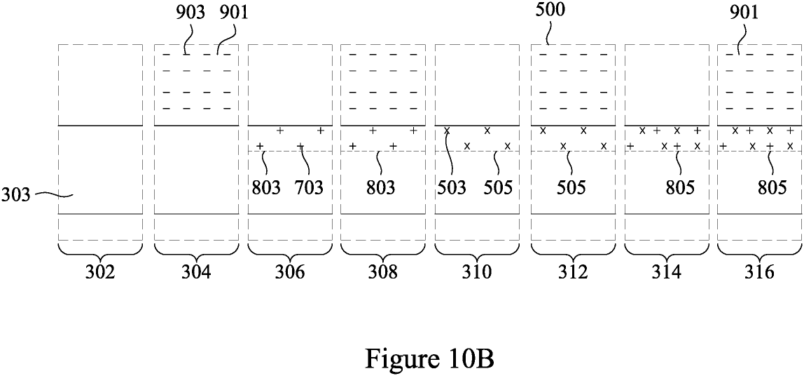

FIGS. 10A-10B illustrate a patterning of the third dopant layer 901 to remove the third dopant layer 901 from the first region 302, the third region 306, the fifth region 310, and the seventh region 314. In an embodiment the third dopant layer 901 may be patterned using, e.g., a photolithographic masking and etching process, although any suitable patterning process may be utilized. As such, once the third dopant layer 901 has been patterned, the third dopant layer 901 remains over the second region 304, the fourth region 308, the sixth region 312, and the eighth region 316.

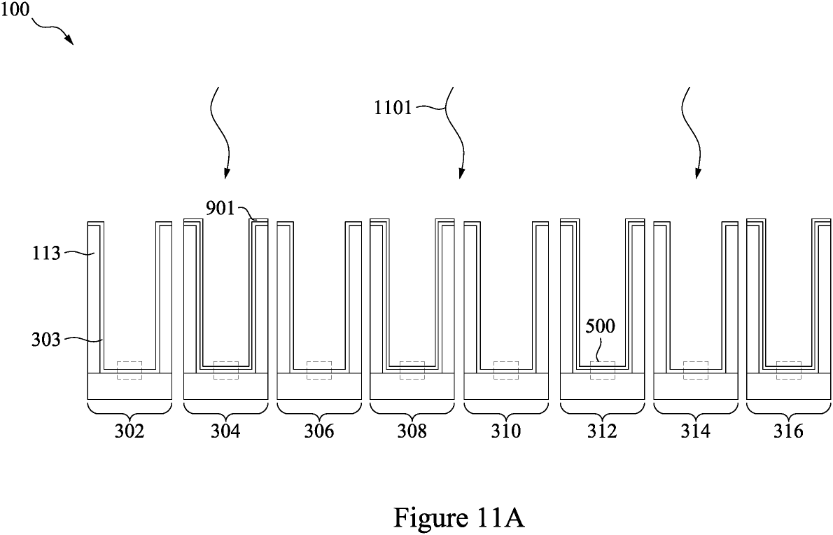

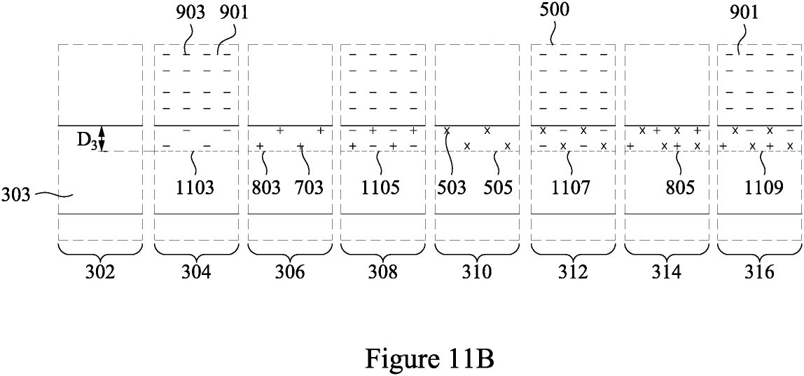

FIGS. 11A-11B illustrate a third annealing process (represented by the curved arrows labeled 1101) that is utilized to drive the third dipole dopants 903 from the third dopant layer 901 into the first dielectric layer 303 over the second region 304, the fourth region 308, the sixth region 312, and the eighth region 316 (but not into the first region 302, the third region 306, the fifth region 310, and the seventh region 314). In an embodiment the third annealing process 1101 may be similar to the first annealing process 501, and may be a thermal anneal wherein the substrate 101 and overlying structures are heated within, e.g., in a furnace, within an inert atmosphere. The third annealing process 1101 may be performed at a temperature of between about 500° C. and about 950° C. If the temperature of the third annealing process 1101 is over 950° C., the overall thermal budget might impact junction and cause issue with process integration. Further, if the temperature if below about 500° C., the dipole cannot form and won’t achieve the desired multiple voltage thresholds.

FIG. 11B illustrates a close up view of the dashed boxes 500 in FIG. 11A, and illustrates the diffusion of the third dipole dopants 903 from the third dopant layer 901 into the first dielectric layer 303 to form a fourth dipole region 1103 (in the second region 304), a fifth dipole region 1105 (in the fourth region 308), a sixth dipole region 1107 (in the sixth region 312) and a seventh dipole region 1109 (in the eighth region 316). In this embodiment the fourth dipole region 1103 comprises dipole dopants of only the third dipole dopants 903 while the fifth dipole region 1105 comprises dipole dopants of both the third dipole dopants 903 and the second dipole dopants 703. Additionally, the sixth dipole region 1107 comprises dipole dopants of both the third dipole dopants 903 and the first dipole dopants 503 and the seventh dipole region 1109 comprises dipole dopants of all of the first dipole dopants 503, the second dipole dopants 703, and the third dipole dopants 903.

As the third dipole dopants 903 diffuse into the first dielectric layer 303 and form the fourth dipole region 1103, the fifth dipole region 1105, the sixth dipole region 1107 and the seventh dipole region 1109, a concentration gradient of the third dipole dopants 903 is formed. In an embodiment the concentration gradient reaches into the first dielectric layer 303 to a third distance D₃. However, any suitable distances may be utilized.

However, while the fourth dipole region 1103 has been formed within the second region 304, the fifth dipole region 1105 has been formed within the fourth region 308, the sixth dipole region 1107 has been formed within the sixth region 312, and the seventh dipole region 1109 has been formed in the eighth region 316, new dipole regions are not formed over all of the region. In particular, because the third dopant layer 901 has been removed from the first region 302, the third region 306, the fifth region 310, and the seventh region 314, these regions are not affected. As such, at this point in the process, the first dielectric layer 303 within the first region 302 remains free of dipole dopants while the second dipole region 803 (within the third region 306), the first dipole regions 505 (within the fifth region 310), and the third dipole region 805 (within the seventh region 314) have no further introduction of new dopants.

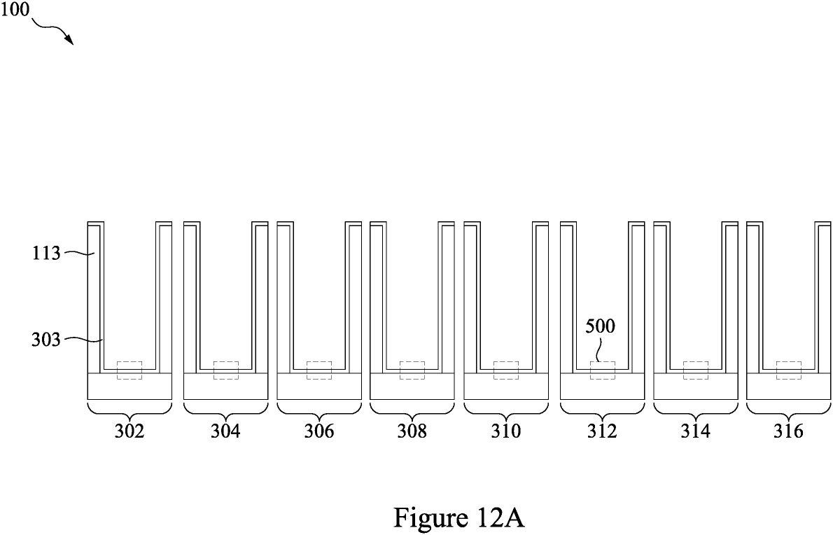

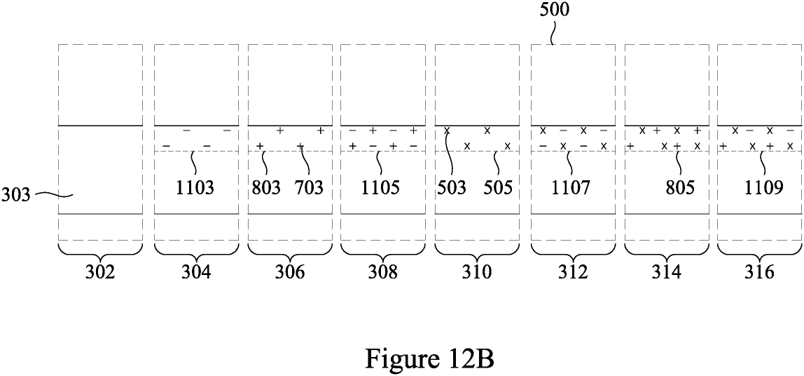

FIGS. 12A-12B illustrate a removal of the third dopant layer 901 from over the structure. In an embodiment the third dopant layer 901 may be removed using one or more etching processes, such as a wet etching process or a dry etching process. However, any suitable removal process may be utilized.

Looking further at FIG. 12B, it can be seen that eight different dipole regions can be formed within the first dielectric layer 303 with the deposition, patterning, annealing, and removal of three dipole dopant layers. In particular, the first region 302 may be free from dipole regions, the second region 304 may comprise the fourth dipole region 1103 (with only the third dipole dopants 903), the third region 306 has the second dipole region 803 (with only the second dipole dopants 703), the fourth region 308 has the fifth dipole region 1105 (with each of the second dipole dopants 703 and the third dipole dopants 903), the fifth region 310 has the first dipole regions 505 (with only the first dipole dopants 503), the sixth region 312 has the sixth dipole region 1107 (with both the first dipole dopants 503 and the third dipole dopants 903), the seventh region 314 has the third dipole region 805 (with both the first dipole dopants 503 and the second dipole dopants 703), and the eighth region 316 has the seventh dipole region 1109 (with all of the first dipole dopants 503, the second dipole dopants 703, and the third dipole dopants 903).

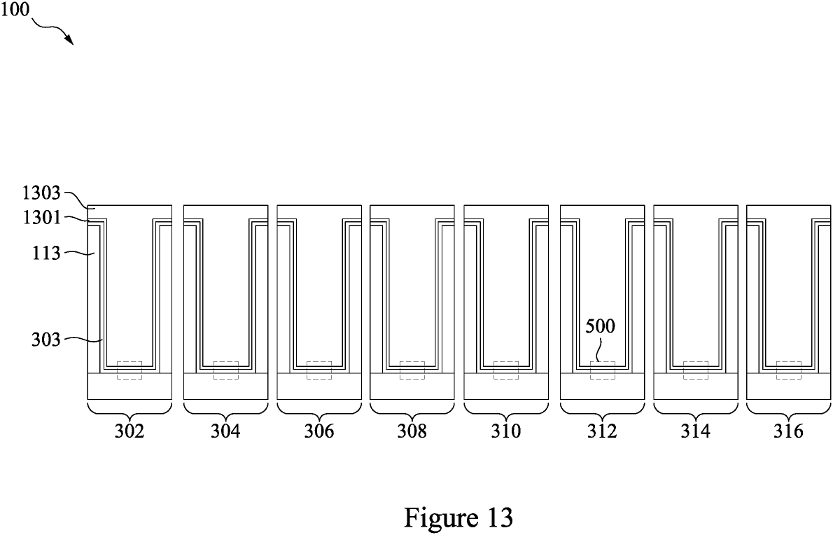

FIG. 13A-13B illustrate deposition of a glue layer 1301 and a fill material 1303 over the first dielectric layer 303. In an embodiment the glue layer 1301 may formed in order to help adhere the overlying fill material 1303 with the underlying first dielectric layer 303 as well as provide a nucleation layer for the formation of the fill material 1303. In an embodiment the glue layer 1301 may be a material such as titanium nitride and may be formed using a similar process such as ALD to a thickness of between about 10 Ǻ and about 100 Ǻ. However, any suitable materials and processes may be utilized.

Once the glue layer 1301 has been formed, the fill material 1303 is deposited to fill a remainder of the opening using the glue layer 1301. However, by forming the different dipole regions as described above, the various tuning layers that are normally utilized to modify threshold voltages (e.g., p-metal work function layers, n-metal work function layers, etc.) can be reduced or even eliminated from the manufacturing process while still being able to achieve different threshold voltages in each of the regions.

In an embodiment the fill material 1303 may be a material such as tungsten, Al, Cu, AlCu, W, Ti, TiAlN, TaC, TaCN, TaSiN, Mn, Zr, TiN, Ta, TaN, Co, Ni, combinations of these, or the like, and may be formed using a deposition process such as plating, chemical vapor deposition, atomic layer deposition, physical vapor deposition, combinations of these, or the like. Additionally, the fill material 1303 may be deposited to a thickness of between about 1000 Å and about 2000 Å, such as about 1500 Å. However, any suitable material may be utilized.

FIG. 14A further illustrates that, after the fill material 1303 has been deposited to fill and overfill the opening, the materials within each of the openings of the first region 302, the second region 304, the third region 306, the fourth region 308, the fifth region 310, the sixth region 312, the seventh region 314, and the eighth region 316 may be planarized to form the first gate stack 1402, the second gate stack 1404, the third gate stack 1406, the fourth gate stack 1408, the fifth gate stack 1410, the sixth gate stack 1412, the seventh gate stack 1414, and the eighth gate stack 1416. In an embodiment the materials may be planarized with the first spacers 113 using, e.g., a chemical mechanical polishing process, although any suitable process, such as grinding or etching, may be utilized.

After the materials of the first gate stack 1402, the second gate stack 1404, the third gate stack 1406, and the fourth gate stack 1408 have been formed and planarized, the materials of the first gate stack 1402, the second gate stack 1404, the third gate stack 1406, and the fourth gate stack 1408 may be recessed and capped with a capping layer 1418. In an embodiment the materials of the first gate stack 1402, the second gate stack 1404, the third gate stack 1406, and the fourth gate stack 1408 may be recessed using, e.g., a wet or dry etching process that utilizes etchants selective to the materials of the first gate stack 1402, the second gate stack 1404, the third gate stack 1406, and the fourth gate stack 1408. In an embodiment the materials of the first gate stack 1402, the second gate stack 1404, the third gate stack 1406, and the fourth gate stack 1408 may be recessed a distance of between about 5 nm and about 150 nm. However, any suitable process and distance may be utilized.

Once the materials of the first gate stack 1402, the second gate stack 1404, the third gate stack 1406, the fourth gate stack 1408, the fifth gate stack 1410, the sixth gate stack 1412, the seventh gate stack 1414, and the eighth gate stack 1416 have been recessed, the capping layer 1418 may be deposited and planarized with the first spacers 113. In an embodiment the capping layer 1418 is a material such as SiN, SiON, SiCON, SiC, SiOC, combinations of these, or the like, deposited using a deposition process such as atomic layer deposition, chemical vapor deposition, sputtering, or the like. The capping layer 1418 may be deposited to a thickness of between about 5 Ǻ and about 200 Ǻ, and then planarized using a planarization process such as chemical mechanical polishing such that the capping layer 1418 is planar with the first spacers 113.

While particular embodiments have been described above to form the various dipole regions with particular materials that have been deposited at particular thicknesses and annealed at particular temperatures and times, the examples provided are intended to be illustrative and are not intended to limit the embodiments to these precise combinations. Rather, any suitable combination of materials, thicknesses, anneal temperatures, and anneal times may be utilized, and all such combinations are fully intended to be included within the scope of the embodiments.

For example, in another particular embodiment, the first dopant layer 305, the second dopant layer 701, and the third dopant layer 901 may all be formed of a similar material and deposited to a similar thickness. However, in order to adjust the threshold voltages, the anneal temperatures of the first annealing process 501, the second annealing process 801, and the third annealing process 1101 may be different from each other.

In yet another embodiment, the first dopant layer 305, the second dopant layer 701, and the third dopant layer 901 may each be deposited with either the same or different materials, but each one may be deposited to have a different thickness from the others. Further in this embodiment the first annealing process 501, the second annealing process 801, and the third annealing process 1101 may be performed at the same temperature.

In still yet another embodiment, the first dopant layer 305, the second dopant layer 701, and the third dopant layer 901 may each be formed using different materials. Further in this embodiment, the first annealing process 501, the second annealing process 801, and the third annealing process 1101 may be performed at the same temperature.

By forming the volume free dipole regions as described above, such that different regions have different dipole fields in different dielectric layers, different transistors can be formed with different threshold voltages. Further, this can be done without the deposition of additional layers (e.g., work function tuning layers) that are left in the final product to adjust the threshold voltages. Without these additional layers present in subsequent manufacturing steps, gap fill conformity problems that would otherwise occur when the devices are scaled down can be avoided.

To help illustrate these benefits, FIG. 14B illustrates one example of the different tunings that can be achieved in the different transistors. In this embodiment each of the different regions may tune the threshold voltages by different amounts from the threshold voltage that would be achieved without the presence of the dipole dopants (represented as threshold voltage Vt₁ that is present within the first region 302). As can be seen by the small differences between the actual and tuning from the target tuning in this figure, the desired threshold voltage tunings can be achieved using the embodiments described herein.

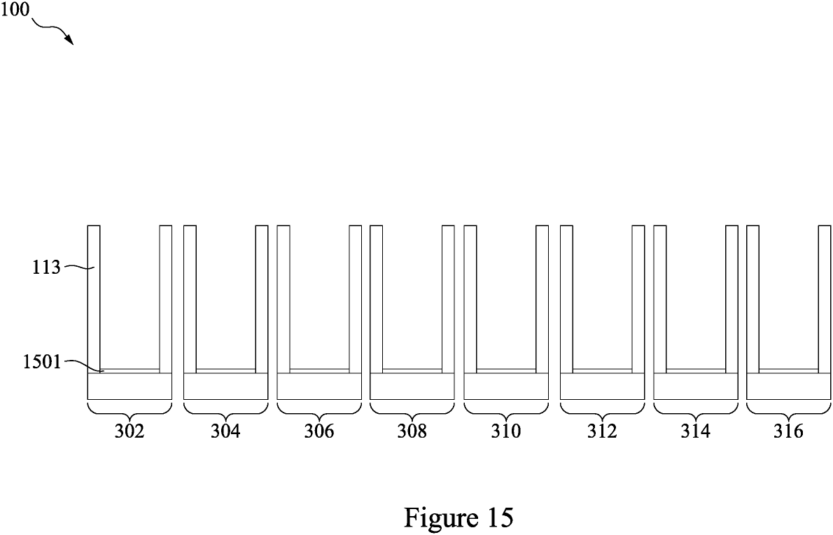

FIG. 15 illustrates another embodiment in which the various dipole regions (e.g., the first dipole regions 505, the second dipole region 803, the third dipole region 805, the fourth dipole region 1103, the fifth dipole region 1105, the sixth dipole region 1107, and the seventh dipole region 1109) are formed within the interfacial layer 1501, instead of being formed in the first dielectric layer 303. In this embodiment the formation of the various dipole regions may be initiated by first forming the interfacial layer 1501.

The interfacial layer 1501 may be formed prior to the formation of the first dielectric layer 303 (described above with respect to FIG. 3). In an embodiment the interfacial layer 1501 may be a material such as silicon dioxide formed through a process such as in situ steam generation (ISSG). As such, the interfacial layer 1501 is formed selectively over the fin 107 and does not extend along sidewalls of the first spacers 113. In another embodiment the interfacial layer may be a high-k material such as HfO₂, HfSiO, HfSiON, HfTaO, HfTiO, HfZrO, LaO, ZrO, Ta₂O₅, combinations of these, or the like, that is deposited to a thickness of between about 5 Ǻ and about 20 Ǻ, such as about 10 Ǻ. As such, in this embodiment the interfacial layer 1501 may extend along both the fin 107 as well as along sidewalls of the first spacers 113. However, any suitable material or process of formation may be utilized.

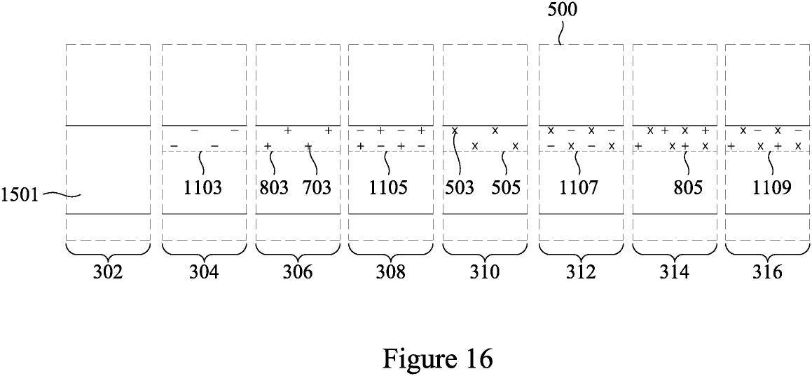

FIG. 16 illustrates a formation of the first dipole regions 505, the second dipole region 803, the third dipole region 805, the fourth dipole region 1103, the fifth dipole region 1105, the sixth dipole region 1107, and the seventh dipole region 1109 (with the interfacial layer 1501 in the first region 302 remaining free of dipole dopants). As such, eight separate and different regions that may or may not include dipole dopants are formed in order to separately tune the individual transistors. In this embodiment, however, the first dipole regions 505, the second dipole region 803, the third dipole region 805, the fourth dipole region 1103, the fifth dipole region 1105, the sixth dipole region 1107, and the seventh dipole region 1109 are formed within the interfacial layer 1501 instead of the first dielectric layer 303 (as described above).

In this embodiment the first dipole regions 505, the second dipole region 803, the third dipole region 805, the fourth dipole region 1103, the fifth dipole region 1105, the sixth dipole region 1107, and the seventh dipole region 1109 may be formed as described above with respect to FIGS. 5 through 11. For example, the first dopant layer 305 may be deposited, annealed, and removed; the second dopant layer 701 may be deposited, annealed, and removed; and the third dopant layer 901 may be deposited, annealed, and removed. However, any suitable methods and materials may be utilized.

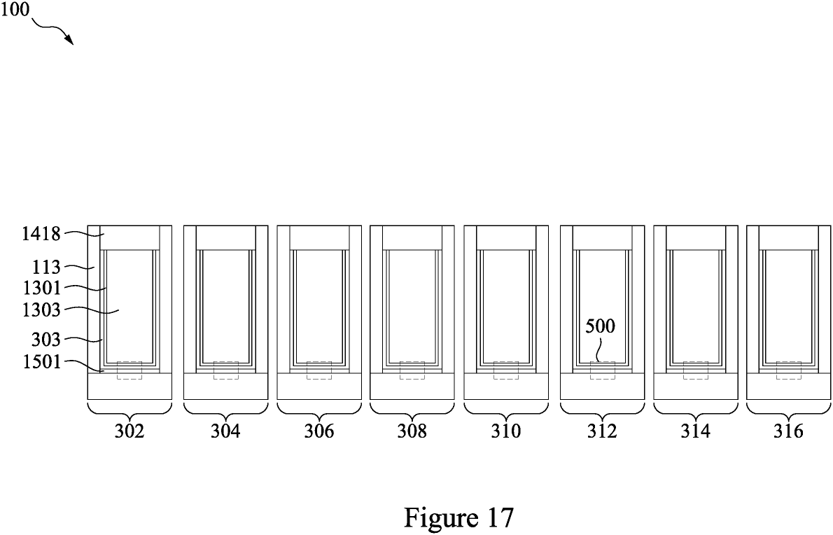

FIG. 17 illustrates that, once the first dipole regions 505, the second dipole region 803, the third dipole region 805, the fourth dipole region 1103, the fifth dipole region 1105, the sixth dipole region 1107, and the seventh dipole region 1109 have been formed, the first dielectric layer 303 is deposited over the first dipole regions 505, the second dipole region 803, the third dipole region 805, the fourth dipole region 1103, the fifth dipole region 1105, the sixth dipole region 1107, and the seventh dipole region 1109 within the interfacial layer 1501. In an embodiment the first dielectric layer 301 may be formed using similar materials and processes as described above with respect to FIG. 3.

Optionally, if desired, additional dipole regions may be formed within the first dielectric layer 303. In this embodiment, the steps of formation discussed above to form the first dipole regions 505, the second dipole region 803, the third dipole region 805, the fourth dipole region 1103, the fifth dipole region 1105, the sixth dipole region 1107, and the seventh dipole region 1109 may be utilized in order to form the additional dipole regions within the first dielectric layer 303.

FIG. 17 additionally illustrates that, once the first dielectric layer 303 has been formed, the glue layer 1301, the fill material 1303, and the capping layer 1418 are manufactured over the first dielectric layer 303. In an embodiment the glue layer 1301, the fill material 1303, and the capping layer 1418 may be manufactured as described above with respect to FIGS. 13-14. However, any suitable methods and materials may be utilized.

The disclosed FinFET embodiments could also be applied to nanostructure devices such as nanostructure (e.g., nanosheet, nanowire, gate-all-around, or the like) field effect transistors (NSFETs). In an NSFET embodiment, the fins are replaced by nanostructures formed by patterning a stack of alternating layers of channel layers and sacrificial layers. Dummy gate stacks and source/drain regions are formed in a manner similar to the above-described embodiments. After the dummy gate stacks are removed, the sacrificial layers can be partially or fully removed in channel regions. The replacement gate structures are formed in a manner similar to the above-described embodiments, the replacement gate structures may partially or completely fill openings left by removing the sacrificial layers, and the replacement gate structures may partially or completely surround the channel layers in the channel regions of the NSFET devices. ILDs and contacts to the replacement gate structures and the source/drain regions may be formed in a manner similar to the above-described embodiments. A nanostructure device can be formed as disclosed in U.S. Pat. Application Publication No. 2016/0365414, which is incorporated herein by reference in its entirety.

By utilizing the embodiments described herein, different transistors can be tuned to have different threshold voltages through the use of dipole dopants. In a particular example, eight different threshold voltages can be achieved by depositing, annealing, and removing three layers. Additionally, by tuning the threshold voltages using dipole dopants, the use of separate work function layers can be avoided. Such avoidance, as devices are further scaled down, allows for a better gap fill in subsequent processing, leading to fewer defects and an overall improvement in the manufacturing process.

In an embodiment a method of manufacturing a semiconductor device includes: forming a first dielectric layer over a first semiconductor fin; forming a second dielectric layer over a second semiconductor fin; forming a first dipole region within the first dielectric layer, the first dipole region comprising a first dipole dopant and a first thickness; and forming a second dipole region within the second dielectric layer, the second dipole region comprising a second dipole dopant and a second thickness, one of the second dipole dopant and the second thickness being different from the first dipole dopant and the first thickness, respectively. In an embodiment the first dipole dopant comprises lanthanum. In an embodiment the second dipole dopant comprises aluminum. In an embodiment the second thickness is different from the first thickness. In an embodiment the forming the first dipole region further comprises a first anneal performed at a first temperature and wherein the forming the second dipole region further comprises a second anneal performed at a second temperature different from the first temperature. In an embodiment the method further includes forming a gate dielectric layer over the first dielectric layer. In an embodiment the second dipole region further comprises the first dipole dopant.

In another embodiment, a method of manufacturing a semiconductor device includes: depositing an interfacial layer over a plurality of semiconductor fins; sequentially depositing, annealing, and removing a plurality of dipole layers, wherein each one of the sequentially depositing, annealing, and removing forms or modifies a dipole region within the interfacial layer; forming a gate dielectric layer over the interfacial layer over the plurality of semiconductor fins; and forming a plurality of gate electrodes over the gate dielectric layer to form a plurality of transistors, each of the plurality of transistors have a different threshold voltage. In an embodiment the plurality of transistors is eight transistors. In an embodiment the sequentially depositing the plurality of dipole layers deposits each of the plurality of dipole layers to a same thickness with a same material and wherein each of the sequentially annealing is performed at different temperatures. In an embodiment the sequentially depositing the plurality of dipole layers deposits each of the plurality of dipole layers to a different thickness and wherein each of the sequentially annealing is performed at a same temperature. In an embodiment the sequentially depositing the plurality of dipole layers deposits each of the plurality of dipole layers with a different material, and wherein each of the sequentially annealing is performed at a same temperature. In an embodiment the depositing the interfacial layer deposits the interfacial layer in physical contact with the plurality of semiconductor fins. In an embodiment the plurality of dipole layers comprises at least two different dopant layers.

In yet another embodiment, a semiconductor device includes: a first transistor comprising a first gate electrode separated from a first semiconductor fin by a first interfacial layer, the first interfacial layer comprising a first dipole region, the first transistor having a first threshold voltage; a second transistor comprising a second gate electrode separated from a second semiconductor fin by a second interfacial layer, the second interfacial layer comprising a second dipole region, the second transistor having a second threshold voltage; a third transistor comprising a third gate electrode separated from a third semiconductor fin by a third interfacial layer, the third interfacial layer comprising a third dipole region, the third transistor having a third threshold voltage; a fourth transistor comprising a fourth gate electrode separated from a fourth semiconductor fin by a fourth interfacial layer, the fourth interfacial layer comprising a fourth dipole region, the fourth transistor having a fourth threshold voltage; a fifth transistor comprising a fifth gate electrode separated from a fifth semiconductor fin by a fifth interfacial layer, the fifth interfacial layer comprising a fifth dipole region, the fifth transistor having a fifth threshold voltage; a sixth transistor comprising a sixth gate electrode separated from a sixth semiconductor fin by a sixth interfacial layer, the sixth interfacial layer comprising a sixth dipole region, the sixth transistor having a sixth threshold voltage; and a seventh transistor comprising a seventh gate electrode separated from a seventh semiconductor fin by a seventh interfacial layer, the seventh interfacial layer comprising a seventh dipole region, the seventh transistor having a seventh threshold voltage, wherein each of the first transistor, the second transistor, the third transistor, the fourth transistor, the fifth transistor, the sixth transistor, and the seventh transistor has a different threshold voltage. In an embodiment the first dipole region comprises a first dipole dopant, and wherein the second dipole region comprises a second dipole dopant different from the first dipole dopant. In an embodiment the third dipole region comprises both the first dipole dopant and the second dipole dopant. In an embodiment the fourth dipole region comprises the first dipole dopant, the second dipole dopant, and a third dipole dopant different from the first dipole dopant and the second dipole dopant. In an embodiment the fifth dipole region comprises the first dipole dopant but not the second dipole dopant and the third dipole dopant. In an embodiment the sixth dipole region comprises the second dipole dopant but not the first dipole dopant and the third dipole dopant.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, the method comprising:
forming a first dielectric layer over a first semiconductor fin;
forming a second dielectric layer over a second semiconductor fin;
forming a first dipole region within the first dielectric layer, the first dipole region comprising a first dipole dopant and a first thickness; and
forming a second dipole region within the second dielectric layer, the second dipole region comprising a second dipole dopant and a second thickness, one of the second dipole dopant and the second thickness being different from the first dipole dopant and the first thickness, respectively.

2. The method of claim 1, wherein the first dipole dopant comprises lanthanum.

3. The method of claim 2, wherein the second dipole dopant comprises aluminum.

4. The method of claim 1, wherein the second thickness is different from the first thickness.

5. The method of claim 1, wherein the forming the first dipole region further comprises a first anneal performed at a first temperature and wherein the forming the second dipole region further comprises a second anneal performed at a second temperature different from the first temperature.

6. The method of claim 1, further comprising forming a gate dielectric layer over the first dielectric layer.

7. The method of claim 1, wherein the second dipole region further comprises the first dipole dopant.

8. A method of manufacturing a semiconductor device, the method comprising:
depositing an interfacial layer over a plurality of semiconductor fins;
sequentially depositing, annealing, and removing a plurality of dipole layers, wherein each one of the sequentially depositing, annealing, and removing forms or modifies a dipole region within the interfacial layer;
forming a gate dielectric layer over the interfacial layer over the plurality of semiconductor fins; and
forming a plurality of gate electrodes over the gate dielectric layer to form a plurality of transistors, each of the plurality of transistors have a different threshold voltage.

9. The method of claim 8, wherein the plurality of transistors is eight transistors.

10. The method of claim 8, wherein the sequentially depositing the plurality of dipole layers deposits each of the plurality of dipole layers to a same thickness with a same material and wherein each of the sequentially annealing is performed at different temperatures.

11. The method of claim 8, wherein the sequentially depositing the plurality of dipole layers deposits each of the plurality of dipole layers to a different thickness and wherein each of the sequentially annealing is performed at a same temperature.

12. The method of claim 8, wherein the sequentially depositing the plurality of dipole layers deposits each of the plurality of dipole layers with a different material, and wherein each of the sequentially annealing is performed at a same temperature.

13. The method of claim 8, wherein the depositing the interfacial layer deposits the interfacial layer in physical contact with the plurality of semiconductor fins.

14. The method of claim 8, wherein the plurality of dipole layers comprises at least two different dopant layers.

15. A semiconductor device comprising:
a first transistor comprising a first gate electrode separated from a first semiconductor fin by a first interfacial layer, the first interfacial layer comprising a first dipole region, the first transistor having a first threshold voltage;
a second transistor comprising a second gate electrode separated from a second semiconductor fin by a second interfacial layer, the second interfacial layer comprising a second dipole region, the second transistor having a second threshold voltage;
a third transistor comprising a third gate electrode separated from a third semiconductor fin by a third interfacial layer, the third interfacial layer comprising a third dipole region, the third transistor having a third threshold voltage;
a fourth transistor comprising a fourth gate electrode separated from a fourth semiconductor fin by a fourth interfacial layer, the fourth interfacial layer comprising a fourth dipole region, the fourth transistor having a fourth threshold voltage;
a fifth transistor comprising a fifth gate electrode separated from a fifth semiconductor fin by a fifth interfacial layer, the fifth interfacial layer comprising a fifth dipole region, the fifth transistor having a fifth threshold voltage;
a sixth transistor comprising a sixth gate electrode separated from a sixth semiconductor fin by a sixth interfacial layer, the sixth interfacial layer comprising a sixth dipole region, the sixth transistor having a sixth threshold voltage; and
a seventh transistor comprising a seventh gate electrode separated from a seventh semiconductor fin by a seventh interfacial layer, the seventh interfacial layer comprising a seventh dipole region, the seventh transistor having a seventh threshold voltage, wherein each of the first transistor, the second transistor, the third transistor, the fourth transistor, the fifth transistor, the sixth transistor, and the seventh transistor has a different threshold voltage.

16. The semiconductor device of claim 15, wherein the first dipole region comprises a first dipole dopant, and wherein the second dipole region comprises a second dipole dopant different from the first dipole dopant.

17. The semiconductor device of claim 16, wherein the third dipole region comprises both the first dipole dopant and the second dipole dopant.

18. The semiconductor device of claim 17, wherein the fourth dipole region comprises the first dipole dopant, the second dipole dopant, and a third dipole dopant different from the first dipole dopant and the second dipole dopant.

19. The semiconductor device of claim 18, wherein the fifth dipole region comprises the first dipole dopant but not the second dipole dopant and the third dipole dopant.

20. The semiconductor device of claim 19, wherein the sixth dipole region comprises the second dipole dopant but not the first dipole dopant and the third dipole dopant.
